(19) United States
(12) Patent Application Publication
(10) Pub. No.: US 2020/0339019 A1
(43) Pub. Date: Oct. 29, 2020

(54) VEHICLE SEAT HAVING AN ELECTRIC HEATING DEVICE

(71) Applicant: VOLKSWAGEN AKTIENGESELLSCHAFT, Wolfsburg (DE)

(72) Inventor: Joerg MARKTSCHEFFEL, Cremlingen (DE)

(73) Assignee: VOLKSWAGEN AKTIENGESELLSCHAFT, Wolfsburg (DE)

(21) Appl. No.: 16/925,482

(22) Filed: Jul. 10, 2020

Related U.S. Application Data
(63) Continuation of application No. PCT/EP2019/050269, filed on Jan. 8, 2019.

(30) Foreign Application Priority Data
Jan. 10, 2018 (DE) 10 2018 200 293.2

(51) Int. Cl. B60N 2/56; H05K 9/00

(52) U.S. Cl. CPC B60N 2/5685; H05B 3/34; H05K 9/0081

(57) ABSTRACT

A vehicle seat that is equipped with an electric heating device and has a cushion surface, wherein a material that is suitable for shielding against electromagnetic radiation is arranged in a flat manner between the cushion surface and the heating device. As a result, a shielding necessary for optimal protection of the vehicle occupant is achieved in a surprisingly simple way by the incorporation of multiple plies of a flat material with components of a transition metal, such as copper or nickel, for example, that is appropriately suitable for shielding against electromagnetic radiation.

This nonprovisional application is a continuation of International Application No. PCT/EP2019/050269, which was filed on Jan. 8, 2019, and which claims priority to German Patent Application No. 10 2018 200 293.2, which was filed in Germany on Jan. 10, 2018, and which are both herein incorporated by reference.

### BACKGROUND OF THE INVENTION

### Field of the Invention

The present invention relates to a vehicle seat that is equipped with an electric heating device and has a cushion surface. In addition, the invention relates to an electric heating device designed to be arranged on a vehicle seat.

### Description of the Background Art

Seat heaters serve to directly warm up the seat surface and backrest of vehicle seats. They usually are formed of heating mats that are incorporated into either the cushion or the seat upholstery, or are bonded therebetween. Incorporated into these mats are wires that heat up when electric current is applied. The resultant heat is delivered through the vehicle seat directly to the person sitting thereon.

The seat heater is regulated by means of sensors and a control unit. Thus, on the one hand the energy output can be adjusted according to need. On the other hand, the response of the heating device is monitored through the sensors so that it is possible to prevent a health hazard due to burning on excessively hot seats or electrical short circuits at broken heating conductors.

As a fundamental rule, every electric voltage produces electric fields, and every electric current produces magnetic fields. Sources of such electromagnetic fields that are used close to the body, in particular including heat heaters, for example, are considered to be high-risk with respect to adverse health effects. This is why applicable guidelines serve to limit exposure of the public to electromagnetic fields in the range up to 300 GHz.

It is also already known that electrically conductive materials, for example metals, reflect high-frequency electromagnetic fields. Therefore, metal films or metal grids, but also metallized substrates, can fully or partially shield high-frequency electromagnetic fields.

DE 10 2009 003 867 A1 relates to an electrically conductive polymer tape or woven polymer fabric based on electrically conductive polymer fibers for laminar heating elements, for example for a seat heater for motor vehicle seats. An electrically conductive, multi-strand knitted tape can be provided with an insulation layer in which is embedded a shield made of a metal braid or an electrically conductive polymer braid, by which means the heating element is made free of electromagnetic radiation.

Polymer heating fabrics for laminar heating elements, in particular for seat heaters in stadium seats or ski lifts, are known from DE 10 2013 100 792 A1. An insulation layer with carrier materials composed of woven glass fabric, woven polymer fabric, or nonwoven material is followed by an adhesive layer composed of composite resin with an electromagnetic shield.

DE 11 2015 001 591 T5, which corresponds to US 2016/0374147, relates to a seat heater with a layered structure in which the heating layer is enclosed by an insulating layer in each case.

EP 2 352 974 B1, which corresponds to US 2011/0290775, discloses a seat heater with an interference reducing structure composed of conductive material to minimize potential interference with an antenna function resulting from operation of the seat heater.

### SUMMARY OF THE INVENTION

It is therefore an object of the present invention to achieve with little effort, in an electric heating device, optimal protection from electromagnetic radiation for the person using the seat when the heating device is employed.

According to an exemplary embodiment of the invention, a vehicle seat is provided, in which a material suitable for shielding against electromagnetic radiation is arranged in a flat manner at least in sections between the cushion surface and the heating device. As a result, a shielding necessary for optimal protection of the vehicle occupant is achieved in a surprisingly simple way, by the application, for example the placement, of one or more plies of a material, in particular a flat material, that is appropriately suitable for shielding against electromagnetic radiation.

It proves especially useful in this context when the flat material has, as a substantial material content, a foam, for example, cut foam, and/or a nonwoven material, or is composed thereof. The foam or the nonwoven material in this context can be made as a planar sheet material or else be prefabricated as contoured shaped parts and incorporated into the seat surface and/or backrest. As a result, the material can also have cushioning functions in addition to and at the same time as the shielding effect, and consequently improve seat comfort.

In addition, it has proven to be especially practical when the flat material has additions of at least one transition metal, in particular of copper, zinc, and/or nickel, by which means an excellent shielding effect can be achieved according to the current findings. For example, the material can be realized as a braid, warp knitted fabric, or weft knitted fabric of a wire-shaped material, wherein a combination with synthetic fibers also cannot be ruled out in order to achieve the desired flexible properties. Moreover, the quantity of the metal used relative to the surface area can be made locally different in order to thus be able to appropriately follow the shape of the heating device, for example, and in this way to concentrate the shielding on those regions that correspond to the arrangement of the heating device.

The material can have a substrate to which a transition metal is added in the form of metal particles as bulk material and/or in powder form. As a result, the desired shielding can be achieved in an especially simple way through the addition of metal powder or metal particles that are mixed into the substrate or applied to it and, if applicable, fixed by an additional adhesive agent. Of course, elements of the cushioning can also be used as a substrate.

The material can have a substrate with a multiplicity of lamellae in whose intermediate spaces the transition metal is embedded so that additional fixing of the metal particles or the metal powder can be dispensed with as a result of a useful orientation of the lamellae, which are realized through cuts in the substrate, for example. Consequently, this variant is also suitable for cushion elements already known per se, which need only be provided with appropriate cuts. Of course, the metal can also be used in the form of fibers.

The flat material can be applied in multiple plies in order to thus further improve the desired shielding effect. In this way, an optimal match to the required shielding can be achieved through an appropriate number of plies or layers. These can be movable relative to one another, for example, so as not to impair the desired flexible properties inside the cushion element.

It is especially preferred for the material thickness of an individual ply or layer of the flat material to be between 0.05 mm and 0.5 mm, in particular between 0.1 mm and 0.2 mm, so that wide applicability is achieved in practice for cushion surfaces that are contoured in almost any desired manner.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a vehicle seat equipped with an electric heating device, in a perspective representation;

FIG. 2 shows a layer structure of a cushion surface of the vehicle seat shown in FIG. 1, in cross-section;

FIG. 3 shows the cushion surface shown in FIG. 2 with a flat material for shielding against electromagnetic radiation, in a top view.

### DETAILED DESCRIPTION

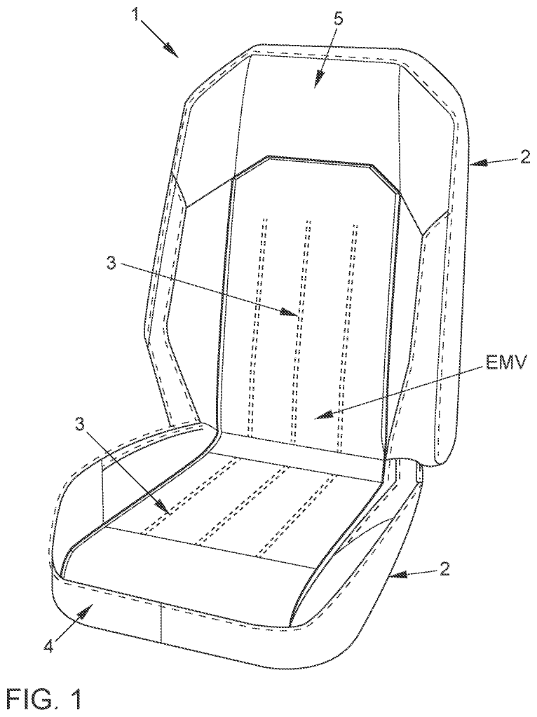

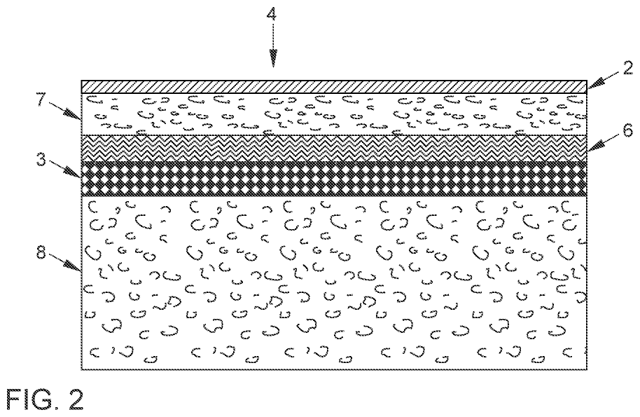

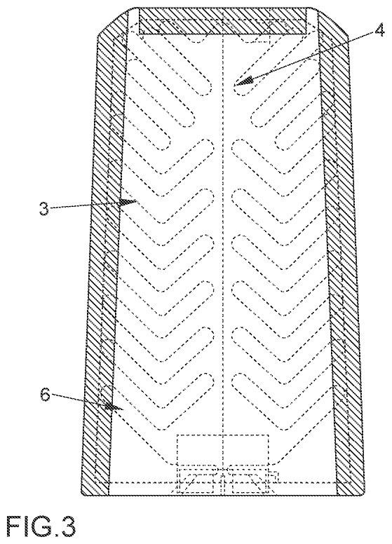

A vehicle seat 1 according to the invention with a cushion surface 2 and with an integrated electric heating device 3 is explained in detail below on the basis of FIGS. 1 to 3. In operation, such heating devices 3 for heating a seat surface 4 or a backrest 5 generate an electromagnetic field EMV, which can bring about adverse effects above a certain field strength. In order to avoid or at least significantly reduce such undesirable effects, a flat material 6 that is suitable for shielding against electromagnetic radiation is arranged at least in sections between the cushion surface 2 and the heating device 3. This material 6, implemented as, e.g., shielding cut foam, above the heating device 3 ensures that the applicable limit values are not exceeded in operation of the seat heater. For this purpose, such a cut foam contains as shielding materials components that shield the full area or portions of it, as for example copper powder or nickel powder. So as not to restrict seat comfort and the technical requirements on the seat heater in this case, an additional laminated foam layer 7 is provided on the inside of the cushion surface 2 above the flat material 6 serving as shielding, as is evident from FIG. 2, in particular; together with the molded foam 8 of the seat surface 4 or the backrest 5 arranged below the heating device 3, this foam layer ensures the desired comfort.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A vehicle seat comprising:
an electric heating device;
a cushion surface; and
a material suitable to shield against electromagnetic radiation being arranged in a flat manner at least in sections between the cushion surface and the heating device.

2. The Vehicle seat according to claim 1, wherein the flat material has, as a substantial content, a foam, cut foam, and/or a nonwoven material.

3. The Vehicle seat according to claim 1, wherein the flat material has additions of at least one transition metal, in particular of copper, zinc, and/or nickel.

4. The Vehicle seat according to claim 1, wherein the material has a substrate to which is added a transition metal in the form of metal particles as bulk material and/or in powder form.

5. The Vehicle seat according to claim 1, wherein the material has a substrate with a plurality of lamellae in whose intermediate spaces transition metal is embedded.

6. The Vehicle seat according to claim 1, wherein the flat material is arranged in multiple plies.

7. The Vehicle seat according to claim 6, wherein a thickness of an individual ply or layer of the flat material is between 0.05 mm and 0.5 mm, or between 0.1 mm and 0.2 mm.

8. An electric heating device for arrangement on a vehicle seat according to claim 1.
